(19) United States
(12) Patent Application Publication
(10) Pub. No.: US 2006/0283572 A1
(43) Pub. Date: Dec. 21, 2006

(54) Heat sink and plasma display device having the same

(76) Inventor: Dong Jin Ha, Yongin-si (KR)

Correspondence Address: CHRISTIE, PARKER & HALE, LLP, PO BOX 7068, PASADENA, CA, 91109-7068, US

(21) Appl. No.: 11/449,565

(22) Filed: Jun. 7, 2006

(30) Foreign Application Priority Data
Jun. 8, 2005 (KR) 10-2005-0048953

(51) Int. Cl. H05K 7/20

(52) U.S. Cl. 165/80.3; 361/704

(57) ABSTRACT

A plasma display device having a heat sink. The heat sink includes a heat sink base adapted to contact a semiconductor device and a plurality of fins extending from the base. Each fin has a fin base and a fin tip distal from the semiconductor device. The fin base is integrally formed with the heat sink base and a fin base width is larger than a fin tip width. The fin base may be tapered toward the fin tip. Alternatively, the fin base may have a constant width and the fin tip may have a constant width.

### CROSS REFERENCE TO RELATED APPLICATION

This application claims priority to and the benefit of Korean Patent Application No. 10-2005-0048953, filed Jun. 8, 2005, in the Korean Intellectual Property Office, the entire content of which is incorporated herein by reference.

### BACKGROUND OF THE INVENTION

1. Field of the Invention

The present invention relates to plasma display devices. More particularly, the present invention relates to a plasma display device which reduces vibration noise.

2. Description of the Prior Art

FIG. 1 shows a conventional driving circuit board mounted on a plasma display panel (PDP). A heat sink is provided in a driving circuit having areas A,B,C of semiconductor equipment employing high power semiconductor devices in order to dissipate heat generated by the high power semiconductor devices. Typically, a plurality of high power switching devices are used in light emitting devices, such as PDPs, in which display cells are formed in cross-over electrodes. Addressing of the display cells of the plasma display panel is performed such that the display cells emit light according to the switching timing of each electrode. Since high power switching devices generate a large amount of heat, if the heat is not easily dissipated to the exterior, not only is the performance of the switching devices deteriorated, but the performance of the driving circuit including the switching devices is also deteriorated. Thus, such high power switching devices must be coupled with heat sinks before they are assembled with a driving circuit. The heat sinks can be manufactured by various fabrication processes, for instance, an extrusion process.

FIG. 2 is an enlarged partial perspective view of a representative area A,B,C of semiconductor equipment of the driving circuit board 200 shown in FIG. 1 including heat sinks coupled with semiconductor devices. The semiconductor device 206 is bonded to the driving circuit board 200 through, for example, soldering and is coupled with the heat sink 202 by means of a screw. In addition, the heat sink 202 is coupled with the driving circuit board 200 by means of a fixing member 204. Heat generated from the semiconductor device 206 during the operation of the driving circuit is dissipated into the exterior through the heat sink 202.

FIG. 3 is a side view illustrating the heat sink 202, which may be subject to vibration generated by the semiconductor device 206.

According to the prior art, a base 202a of the heat sink 202 which makes contact with the semiconductor device 206 is subject to a horizontal force F due to the vibration generated by the semiconductor device 206. Accordingly, a plurality of fins 202b of the heat sink 202 installed perpendicularly to the base 202a are vibrated perpendicularly to the horizontal force F (bending motion direction), thus generating noise. The noise may become significant in a natural frequency band of the fins 202b.

### SUMMARY OF THE INVENTION

In one exemplary embodiment, a plasma display device is provided equipped with a heat sink capable of reducing noise. The heat sink includes a heat sink base adapted to contact a semiconductor device and a plurality of fins extending from the heat sink base, each fin of the plurality of fins including a fin base and a fin tip distal from the semiconductor device. The fin base is integrally formed with the heat sink base; and a fin base width is larger than a fin tip width. Each fin of the plurality of fins has a width gradually reduced from the fin base to the fin tip, and more specifically, one or two surfaces of each fin is inclined to reduce the width of the fin from the fin base to the fin tip. In one exemplary embodiment, the fin base width is constant and the fin tip width is constant and a fin base length is greater than half of a total fin length.

In another exemplary embodiment, the plasma display device provided containing the heat sink includes a plasma display panel, a chassis for supporting a rear surface of the plasma display panel, a plurality of circuit boards electrically connected to a lower surface of the chassis, and a semiconductor device provided in the circuit boards.

### BRIEF DESCRIPTION OF THE DRAWINGS

FIG. 1 is a perspective view illustrating circuitry on a surface of a conventional plasma display panel.

FIG. 2 is an enlarged partial perspective view of a representative portion of the plasma display panel of FIG. 1.

FIG. 3 is a side view illustrating a conventional heat sink.

FIG. 4 is a side view illustrating a heat sink according to an embodiment of the present invention.

FIG. 5 is a side view illustrating a heat sink according to another embodiment of the present invention.

FIG. 6 is a side view illustrating a heat sink according to yet another embodiment of the present invention.

FIG. 7 is a partial sectional view of a plasma display device equipped with a heat sink according to still another embodiment of the present invention.

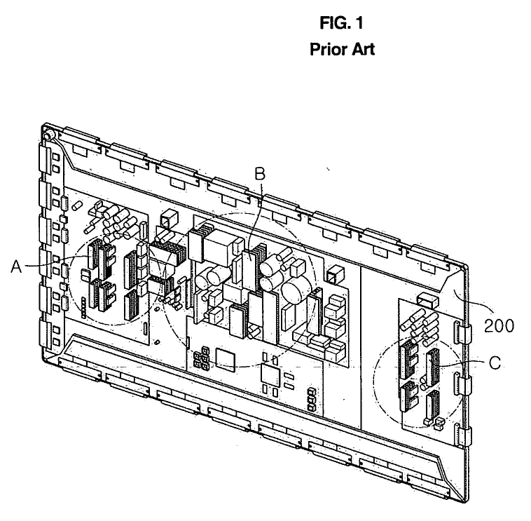

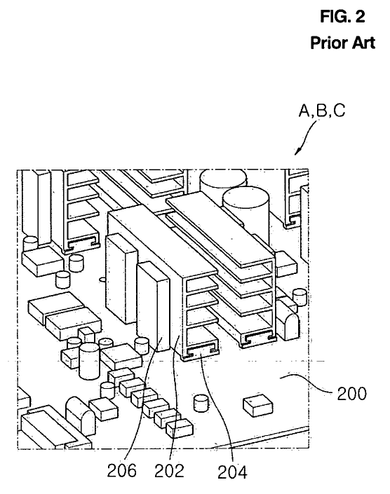

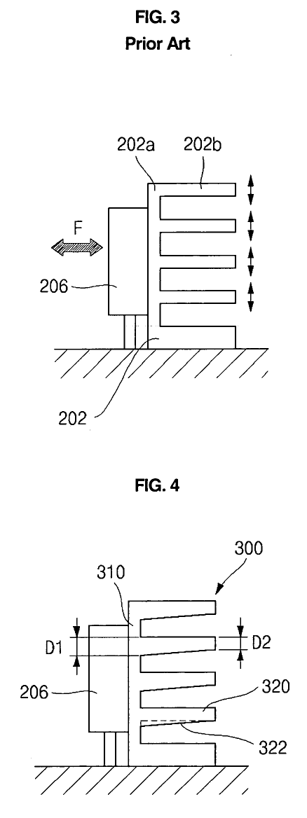

### DETAILED DESCRIPTION

Referring to FIG. 4, a heat sink 300 according to an embodiment of the present invention includes a heat sink base 310 and a plurality of fins 320 integrally formed with the base 310 and extending from the base 310. The heat sink 300 is coupled to the semiconductor device 206 by a bolt and a nut, the semiconductor device generating heat to be dissipated by the heat sink.

According to an embodiment of the present invention, a fin base 325 integrally formed with the heat sink base 310 has a width (D1) larger than a width (D2) of a fin tip 327.

In addition, the width of the fin 320 is gradually reduced from the fin base 325 to the fin tip 327. That is, one surface of the fin 320 is an inclined surface 322 so that the width of the fin 320 is gradually reduced from the fin base 325 to the fin tip 327.

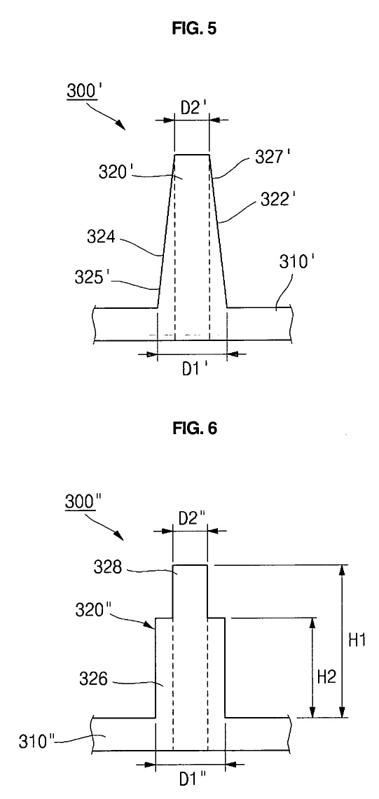

Alternatively, as shown in FIG. 5, another embodiment depicts a heat sink 300′. Two surfaces 322′, 324 of the fin 320′ may be inclined. In this case, the fin 320′ has a trapezoidal cross-sectional shape so that the width of the fin 320′ is gradually reduced from the fin base 325′ to the fin tip 327′. Thus, the width (D1′) of the fin base 325′ is larger than the width (D2′) of the fin tip 327′.

The heat sink 300′ according to the embodiment of the present invention shown in FIG. 5 includes a fin base 325′ integrally formed with the heat sink base 310′, the fin base 325′ being wider than a conventional fin base. Therefore, vibration of the fin 320′ in the bending motion direction thereof may be minimized, thus minimizing noise caused by the vibration of the fin 320′.

FIG. 6 is an enlarged view illustrating a fin of a heat sink 300″ according to yet another embodiment of the present invention. Referring to FIG. 6, the width of the fin base 326 integrally formed with the heat sink base 310 is larger than the width of the fin tip 328. Rather than being tapered, the fin base 326 has a constant width (D1′″) and a fin tip 328 has a constant width (D2″) smaller than the fin base width (D1″). In order to minimize the vibration transferred to the fin 320″ from the heat sink base 310″, the fin base 326 has a relatively larger width (D1″) than the fin tip 328. The width D2″ corresponds generally to the width of a conventional fin.

In one exemplary embodiment, the height (H2) of the fin base 326 is greater than half of the total height H1 of the fin 320″ (that is H2>0.5H1). This ratio of the height of the fin base 326 to the fin tip 328 effectively shields the vibration transferred to the fin 320″ from the heat sink base 310″. If the relative height H2 is too small, it is difficult to effectively shield the vibration transferred to the fin 320″ from the heat sink base 310″.

According to the embodiment of the present invention shown in FIG. 6, since the fin base 326 has a relatively larger width (D1″), the vibration of the fin 320″ in the bending motion direction may be restricted even if the vibration generated from the semiconductor device is transferred to the fin 320″ through the heat sink base 310″, so that noise caused by the vibration of the fin 320″ may be reduced.

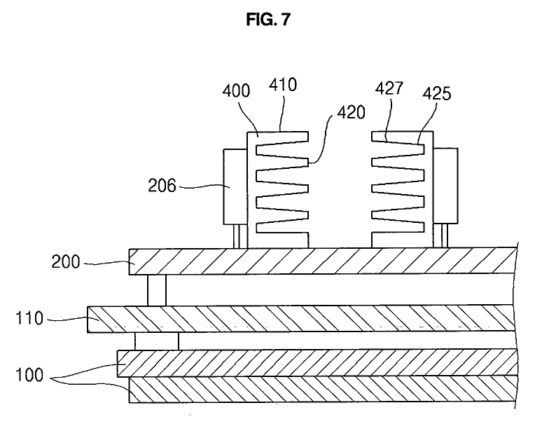

Referring now to FIG. 7, a heat sink 400 according to any of the above embodiments of the present invention, or combinations thereof, may be applied to a plasma display device including a PDP 100, a chassis 110 for supporting a rear surface of the PDP 100, a plurality of circuit boards 200 electrically connected to a lower surface of the chassis 110, and a plurality of semiconductor devices 206 provided in the circuit boards 200. The heat sink 400 of FIG. 7 shows a heat sink having an outer fin 410 similar to that of fin 320 of FIG. 4 with inner fin 420.

In order to dissipate heat generated by the semiconductor device 206, the heat sink 400 is installed on the circuit board 200 so that the heat sink makes contact with the semiconductor device 206. As described above, the heat sink 400 includes fins 420, 420 having a fin base 425 with a relatively larger width than a fin tip 427, so that the heat sink has sufficient bending strength.

As described, according to the heat sink and the plasma display device equipped with the heat sink of the present invention, the strength of the fin base is reinforced so that vibration of the fin in the bending motion direction caused by vibration by the semiconductor device may be restricted, thereby significantly reducing noise generated by the heat sink. Since noise generated from the heat sink can be reduced, noise reduction effects of the plasma display device equipped with the heat sink can be enhanced, thereby improving reliability of the plasma display device.

Although exemplary embodiments of the present invention have been described for illustrative purposes, those skilled in the art will appreciate that various modifications, additions and substitutions are possible, without departing from the scope and spirit of the invention as disclosed in the accompanying claims.

What is claimed is:

1. A heat sink comprising:
a heat sink base adapted to contact a semiconductor device; and
a plurality of fins extending from the heat sink base, each fin of the plurality of fins including a fin base and a fin tip distal from the semiconductor device,
wherein the fin base is integrally formed with the heat sink base and
wherein a fin base width is larger than a fin tip width.

2. The heat sink as claimed in claim 1, wherein each fin of the plurality of fins has a width gradually reduced from the fin base to the fin tip.

3. The heat sink as claimed in claim 2, wherein one surface of each fin is inclined to reduce the width of the fin from the fin base to the fin tip.

4. The heat sink as claimed in claim 2, wherein two surfaces of a fin are inclined to reduce the width of the fin from the fin base to the fin tip.

5. The heat sink as claimed in claim 1, wherein the fin base width is constant and the fin tip width is constant.

6. The heat sink as claimed in claim 5, wherein a fin base length is greater than half of a total fin length.

7. A plasma display device comprising:
a plasma display panel;
a plurality of circuit boards having at least one semiconductor device;
a chassis for supporting the plasma display panel on one chassis side and for supporting the plurality of circuit boards on an opposing chassis side; and
a heat dissipation unit for dissipating heat generated by the at least one semiconductor device, the heat dissipation unit including a heat sink installed on the semiconductor device, the heat sink having a heat sink base adapted to contact the at least one semiconductor device and a plurality of fins extending from the heat sink base,
wherein each fin of the plurality of fins has a fin base integrally formed with the heat sink base and a fin tip distal from the at least one semiconductor device and
wherein a fin base width is larger than a fin tip width.

8. The plasma display device as claimed in claim 7, wherein each fin of the plurality of fins has a width gradually reduced from the fin base to the fin tip.

9. The plasma display device as claimed in claim 8, wherein one surface of each fin is inclined to reduce the width of the fin from the fin base to the fin tip.

10. The plasma display device as claimed in claim 8, wherein two surfaces of a fin are inclined to reduce the width of the fin from the fin base to the fin tip.

11. The plasma display device as claimed in claim 7, wherein the fin base width is constant and the fin tip width is constant.

12. The plasma display device as claimed in claim 11, wherein a fin base length is greater than half of a total fin length.
